(19) United States
(12) Patent Application Publication
(10) Pub. No.: US 2011/0031574 A1
(43) Pub. Date: Feb. 10, 2011

(54) SOLID-STATE IMAGING DEVICE, IMAGING APPARATUS, AND MANUFACTURING METHOD OF SOLID-STATE IMAGING DEVICE

(75) Inventor: Masanori Nagase, Miyagi (JP)

Correspondence Address: KIMBLE INTELLECTUAL PROPERTY LAW, PLLC, 1701 PENNSYLVANIA AVE., NW, SUITE 300, WASHINGTON, DC, 20006, US

(73) Assignee: FUJIFILM Corporation, Tokyo (JP)

(21) Appl. No.: 12/699,866

(22) Filed: Feb. 3, 2010

(30) Foreign Application Priority Data
Feb. 4, 2009 (JP) 2009-023663

(51) Int. Cl. H01L 31/0232; H01L 31/18

(52) U.S. Cl. 257/432; 438/69; 257/E31.127

(57) ABSTRACT

A solid-state imaging device includes: a first well layer which is provided in a semiconductor substrate, has a conductivity type that is opposite to a conductivity type of the semiconductor substrate, and includes photoelectric conversion elements and a reading unit for reading signals corresponding to charges generated in the respective photoelectric conversion elements; a second well layer provided in the semiconductor substrate and having the conductivity type that is opposite to the conductivity type of the semiconductor substrate; and a light shield layer which is provided over an area where the photoelectric conversion elements are provided, has openings over the respective photoelectric conversion elements, and has contact portions that are in contact with the second well layer.

### CROSS-REFERENCE TO RELATED APPLICATIONS

This application claims the benefit of Japanese Patent Application JP 2009-023663, filed Feb. 4, 2009, the entire content of which is hereby incorporated by reference, the same as if set forth at length.

### FIELD OF THE INVENTION

The present invention relates to a solid-state imaging device, an imaging apparatus having it, and a manufacturing method of the solid-state imaging device.

### BACKGROUND OF THE INVENTION

To minimize smear which is noise specific to them, CCD image sensors are designed so that the distance between a light shield layer and a silicon substrate is made as short as possible. For example, in latest pixels of approximately a 2-μm square, the equivalent oxide thickness (EOT) of an insulating layer between a light shield layer and a silicon substrate is as small as about 100 nm which is about two times that of a gate insulating layer.

A general manufacturing process of a CCD image sensor having a general configuration is as follows. After such elements as photoelectric conversion elements are formed in a p-well layer, transfer electrodes made of polysilicon or the like are formed on a substrate. After an insulating layer is formed on those members, a light shield layer is formed. Then, an insulating layer is formed on the light shield layer and contact holes are formed through the insulating layer. Aluminum interconnections which are connected to the p-well layer are buried in the contact holes, whereby the potential of the light shield layer is fixed to the ground potential.

In the above manufacturing process, a step of depositing an interlayer insulating layer, a step of forming contact holes, and other steps exist between the formation of the light shield layer and the connection of the light shield layer to the p-well layer. The light shield layer is in a floating state during that course. As a result, the light shield layer and the p-well layer may be given different potentials because of, for example, charging-up of the light-shield layer in those steps.

As described above, solid-state imaging devices that are highly increased in miniaturization have such a structure that the light shield layer, the silicon substrate, and the gate insulating layer formed between them cause a non-negligible parasitic MOS electric field effect because of the reduced distance between the light shield layer and the p-well layer, the potential difference between the light shield layer and the p-well layer, and other factors. This parasitic MOS electric field effect causes various problems such as increase in dark current which lowers the SN ratio.

Conventionally, to suppress the parasitic MOS electric field effect, various configurations have been proposed in which the light shield layer and the silicon substrate are given the same potential during manufacture (refer to JP-A-63-142859, JP-A-7-94699, JP-A-11-177078, JP-A-2007-189022 and JP-A-2002-141490). However, all of these configurations are such that the light shield layer is in contact with the semiconductor substrate in which the photoelectric conversion elements or the CCD is formed. Therefore, the potential of the light shield layer cannot be varied during use of the device.

JP-A-2003-37262 proposes a solid-state imaging device which realizes a low smear level, a low read voltage, and a low dark current by making it possible to apply a negative voltage to the light shield layer. However, the configurations of JP-A-63-142859, JP-A-7-94699, JP-A-11-177078, JP-A-2007-189022 and JP-A-2002-141490 cannot utilize this advantage.

### SUMMARY OF THE INVENTION

The present invention has been made in the above circumstances, and an object of the invention is therefore to provide a solid-state imaging device which is low in dark current, an imaging apparatus having it, and a manufacturing method of the solid-state imaging device.

A solid-state imaging device according to the invention comprises a first well layer which is formed in a semiconductor substrate, has a conductivity type that is opposite to a conductivity type of the semiconductor substrate, and includes photoelectric conversion elements and a reading unit for reading signals corresponding to charges generated in the respective photoelectric conversion elements; a second well layer formed in the semiconductor substrate and having the conductivity type that is opposite to the conductivity type of the semiconductor substrate; and a light shield layer which is formed over an area where the photoelectric conversion elements are formed, has openings over the respective photoelectric conversion elements, and has contact portions that are in contact with the second well layer.

An imaging device according to the invention comprises the above solid-state imaging device.

A manufacturing method of a solid-state imaging device according to the invention comprises a first step of forming, in a semiconductor substrate, a first well layer having a conductivity type that is opposite to a conductivity type of the semiconductor substrate and a second well layer having the conductivity type that is opposite to the conductivity type of the semiconductor substrate; a second step of forming, in the first well layer, photoelectric conversion elements and a reading unit for reading signals corresponding to charges generated in the respective photoelectric conversion elements; a third step, executed after the second step, of exposing portions of the second well layer by forming openings in a part, coextending with the second well layer, of a material layer that covers the semiconductor substrate; and a fourth step of forming a light shield layer by depositing a light shield material so that it comes into contact with the portions, exposed through the openings, of the second well layer and forming openings through the light shield material over the respective photoelectric conversion elements.

The invention can provide a solid-state imaging device which is low in dark current, an imaging apparatus having it, and a manufacturing method of the solid-state imaging device.

### BRIEF DESCRIPTION OF THE DRAWINGS

FIG. 1 is a schematic plan view of a solid-state imaging device according to an embodiment of the present invention.

FIG. 2 is a schematic sectional view taken along line A-A′ in FIG. 1.

FIG. 3 is a schematic sectional view taken along line B-B′ in FIG. 1.

FIGS. 4A, 4B and 4C are schematic sectional views for description of a manufacturing method of the solid-state imaging device of FIG. 1.

### DETAILED DESCRIPTION OF THE INVENTION

An embodiment of the present invention will be hereinafter described with reference to the drawings.

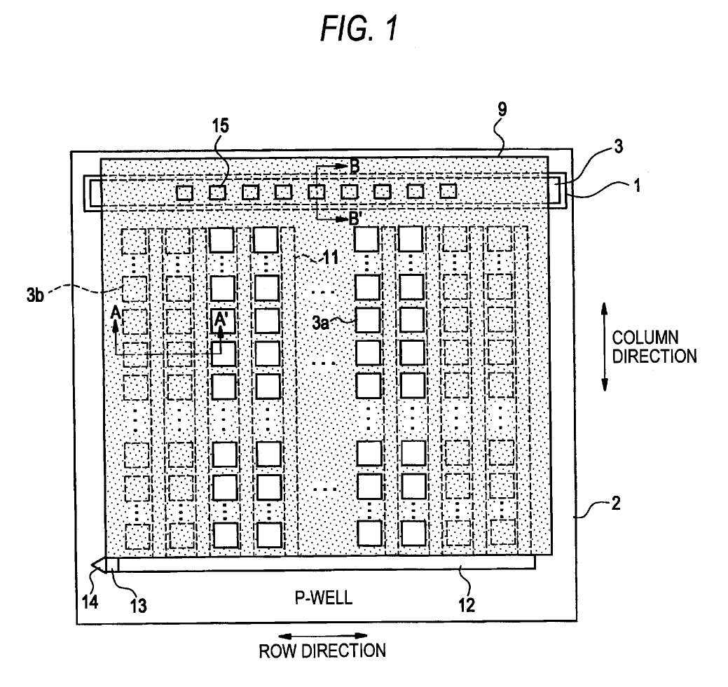

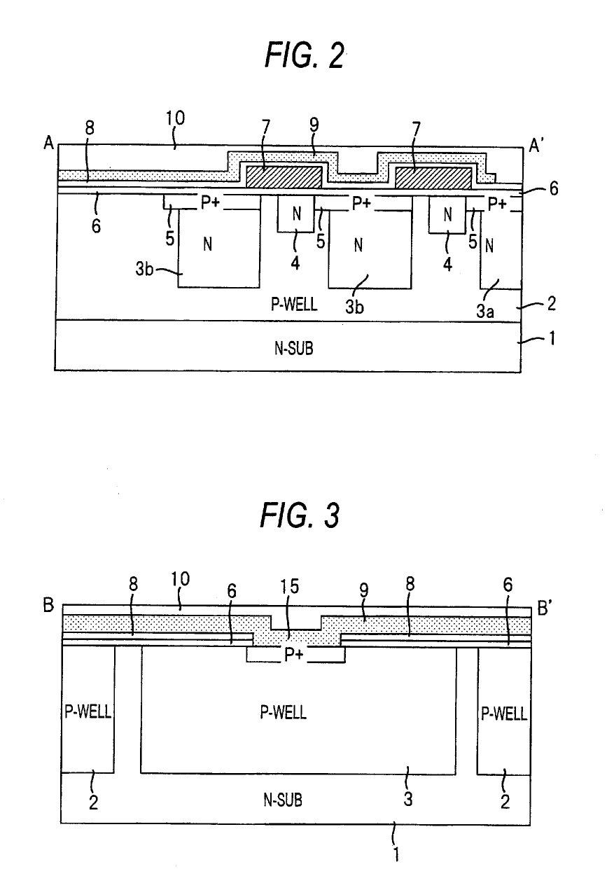

FIG. 1 is a schematic plan view of a solid-state imaging device according to the embodiment of the invention. FIG. 2 is a schematic sectional view taken along line A-A′ in FIG. 1. FIG. 3 is a schematic sectional view taken along line B-B′ in FIG. 1. This solid-state imaging device is used being incorporated in an imaging apparatus that is built in a cell phone, an electronic endoscope, or the like or an imaging apparatus such as a digital camera or a digital video camera.

A p-well layer 2 and a p-well layer 3 are formed in an n-type silicon substrate 1 adjacent to its surface so as to be spaced from each other. Plural photoelectric conversion elements are formed in the p-well layer 2 so as to be arranged two dimensionally, that is, in a row direction and a column direction which is perpendicular to the row direction (in the example of FIG. 1, so as to assume a square lattice). The plural photoelectric conversion elements include photodetection photoelectric conversion elements 3a (indicated by solid lines in FIG. 1) for detecting light coming from a subject and black level detection photoelectric conversion elements 3b (indicated by broken lines in FIG. 1) for detecting a black level of the photodetection photoelectric conversion elements 3a.

Each photoelectric conversion element has an n-type impurity layer that is formed adjacent to the surface of the p-well layer 2. A photodiode (photoelectric conversion element) for generating charge in response to light and storing the generated charge is formed by the pn junction of the n-type impurity layer and the p-well layer 2. For dark current reduction and other purposes, a high-concentration p-type impurity layer 5 is formed in a surface portion of the n-type impurity layer.

The plural photoelectric conversion elements are arranged in such a manner that plural lines each of which consists of plural photoelectric conversion elements that are arranged in the row direction are arranged in the column direction. Each line includes black level detection photoelectric conversion elements 3b and photodetection photoelectric conversion elements 3a. In each line, two black level detection photoelectric conversion elements 3b, for example, are disposed at each end and plural photodetection photoelectric conversion elements 3a are disposed between those sets of black level detection photoelectric conversion elements 3b.

Charge that is generated in each photoelectric conversion element is read into an associated one of plural vertical charge transfer members 11 which are arranged in the column direction so as to correspond to the respective columns of photoelectric conversion elements, and is then transferred through the associated vertical charge transfer member 11. Each vertical charge transfer member 11 is composed of a charge transfer channel 4 which is an n-type impurity layer formed in the p-well 2 and a transfer electrode 7 which is formed over the charge transfer channel 4 with a gate insulating layer 6 (ONO layer, silicon oxide layer, or the like) interposed in between.

A horizontal charge transfer member 12 is provided adjacent to one ends of the plural vertical charge transfer members 11. The horizontal charge transfer member 12 transfers, in the row direction, charges that have been transferred from the vertical charge transfer members 11. A floating diffusion layer 13 is connected to one end of the horizontal charge transfer member 12 and a source follower amplifier 14 is connected to the floating diffusion layer 13. Charge that has been transferred through the horizontal charge transfer member 12 is converted into an output voltage signal that corresponds to the charge amount by the floating diffusion layer 13 and the source follower amplifier 14. The horizontal charge transfer member 12, the floating diffusion layer 13, and the source follower amplifier 14 are also formed in the p-well 2. The vertical charge transfer members 11, the horizontal charge transfer member 12, the floating diffusion layer 13, and the source follower amplifier 14 constitute a reading unit for reading out, to the outside, a voltage signal that corresponds to charge generated in each photoelectric conversion element. The reading unit is not limited to a CCD circuit as shown in FIG. 1 and may be a CMOS circuit.

A light shield layer 9 made of tungsten or the like is formed over an area where the photodetection photoelectric conversion elements 3a, the black level detection photoelectric conversion elements 3b, and the vertical charge transfer members are formed. Having openings only over the respective photodetection photoelectric conversion elements 3a, the light shield layer 9 shields the members other than the photodetection photoelectric conversion elements 3a from light and thereby prevents light from entering the black level detection photoelectric conversion elements 3b or the vertical charge transfer members 11.

The light shield layer 9 extends to over the p-well layer 3 and has contact portions 15 there which are in contact with the p-well layer 3. The plural contact portions 15 are formed on the surface of the p-well layer 3 so as to be arranged in the row direction.

As shown in FIG. 2, the gate insulating layer 6 is formed on the p-well layer 2 and the transfer electrodes 7 made of polysilicon or the like are formed on the gate insulating layer 6. An insulating layer 8 which is an oxide layer, a nitride layer, or the like is formed on the transfer electrodes 7, and the light shield layer 9 is formed on the insulating layer 8. An oxide layer 10 which is a BPSG layer or the like is formed on the light shield layer 9, and intralayer lenses, color filters, and microlenses (none of those are shown) are formed on the oxide layer 10.

As shown in FIG. 3, the gate insulating layer 6 extends to over the p-well layer 3 and the insulating layer 8 extends to cover that part of the gate insulating layer 6. The light shield layer 9 extends to cover that part of the insulating layer 8, and the oxide layer 10 extends to cover that part of the light shield layer 9.

As shown in FIG. 3, openings are formed through those parts of the gate insulating layer 6 and the insulating layer 8 which are formed on the surface of the p-well layer 3. The contact portions 15 of the light shield layer 9 are in contact with the p-well layer 3 through the respective openings. As shown in FIG. 3, it is preferable that high-concentration p-type impurity layers be formed adjacent to the surface of the p-well layer 3 and the contact portions 15 be in contact with the respective high-concentration p-type impurity layers instead of being in direct contact with the p-well layer 3.

Next, a manufacturing method of the above-configured solid-state imaging device will be described.

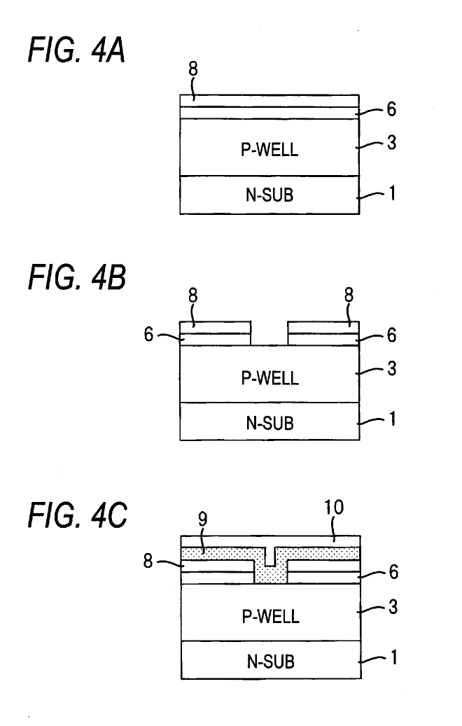

FIGS. 4A-4C are schematic sectional views for description of a manufacturing method of the solid-state imaging device of FIG. 1. FIGS. 4A-4C are schematic sectional views of the p-well layer 3 and its neighborhood in the process of manufacture. First, a p-well layer 2 and a p-well layer 3 are formed in an n-type silicon substrate 1 (n-type epitaxially grown layer) by ion implantation or the like so as to be spaced from each other. Then, a gate insulating layer 6 is formed on the entire n-type silicon substrate 1. After a device area including photoelectric conversion elements 3a and 3b, a reading unit, etc. is formed in the p-well layer 2, an insulating layer 8 is deposited so as to cover the entire silicon substrate 1 by thermal CVD (HTO), thermal TEOS-CVD, or the like. The structure of FIG. 4A is thus completed.

Then, contact holes are formed through that part of the material layer (gate insulating layer 6 and insulating layer 8) which covers the p-well layer 3 by resist patterning and etching (see FIG. 4B).

Then, a light shield layer 9 is formed by depositing a tungsten layer by CVD or PVD and forming openings only over the photodetection photoelectric conversion elements 3a by photolithography and etching. As a result of this step, the light shield layer 9 comes into contact with the p-well layer 3 through the contact holes to form contact portions 15. Since the light shield layer 9 comes into contact with the p-well layer 3 when it is formed, the potentials of the light shield layer 9 and the p-well layer 3 will be kept the same during the ensuing manufacturing process. The light shield layer 9 may be a stack of a tungsten layer and a titanium nitride layer or a stack of a tungsten layer, a titanium nitride layer, and a titanium layer. The light shield layer 9 may have some other layer structure as long as it exhibits necessary light shield performance and conductivity.

Then, a BPSG, thermal TEOS, plasma TEOS, HDP-SiO, SOG, or like oxide layer 10 (interlayer insulating layer) that is high in buriability and flatness is deposited, whereby the structure of FIG. 4C is completed. The oxide layer 10 may be a single layer, a stack, or a layer formed by a combination of several deposition methods. It may be replaced by an insulating layer other than an oxide layer.

Then, contact hole formation, metal deposition, resist patterning, and etching are performed. This metal layer is not shown in FIG. 4C because in the area shown in FIG. 4C the metal layer is removed completely after the deposition. Usually, the metal layer is deposited by sputtering Al or an Al alloy such as AlSiCu. The metal layer may be a single layer or a stack. And the metal layer may have a barrier metal structure such as TiN/Ti, a silicide structure such as TiN/Ti/TiSi, a sandwich structure using a barrier metal such as TiN, or the like. As such, the structure of the metal layer is not limited to any structure as long as it is a common metal structure.

Then, a device (not shown) is completed by forming elements of a common optical system such as downward convex intralayer lenses, upward convex intralayer lenses, a planarization layer, color filters, and microlenses. These optical system elements are not indispensable, that is, whether each of these (sets of) optical system elements should be provided is determined according to the use and the necessary performance of an image sensor intended.

In the above-configured solid-state imaging device, the n-type silicon of the n-type silicon substrate 1 exists between the p-well layers 2 and 3 and a parasitic pnp bipolar structure is formed there. Therefore, the p-well layers 2 and 3 are given approximately the same potential. Since the p-well layer 3 is in contact with the light shield layer 9, the p-well layer 2 and the light shield layer 9 can always be kept at the same potential during manufacture of the solid-state imaging device. This makes it possible to prevent a parasitic MOS electric field effect from occurring due to a plasma surge etc.

Incidentally, the operating voltages for the photoelectric conversion elements and the reading unit which are formed in the p-well layer 2 include a high-level voltage VH (in general, 15 V) that is applied to each transfer electrode 7 in reading charges from the associated photoelectric conversion elements into the associated vertical charge transfer member 11, a middle-level voltage VM (in general, 0 V) that is applied to each transfer electrode 7 to form a potential well in the charge transfer channel 4 of the associated vertical charge transfer member 11, a low-level voltage VL (in general, −8 V) that is applied to each transfer electrode 7 to form a potential barrier in the associated charge transfer channel 4, and a ground potential that is given to the p-well layer 2.

A maximum electric field develops in the gate insulating layer 6 when the voltage VL, among the above operating voltages, is applied to the transfer electrodes 7. This is because when the voltage VL is applied to the transfer electrodes 7, a pinning state is established and almost all of the voltage VL develops across the gate insulating layer 6.

Taking the above into consideration, since the insulating layer formed between the light shield layer 9 and the n-type silicon substrate 1 is as thick as or thicker than the gate insulating layer 6, such problems as dielectric breakdown do not occur even if a bias of 8 V (equivalent to the voltage VL) is exerted between the light shield layer 9 and the p-well layer 2 during manufacture. That is, a parasitic MOS electric field effect can be suppressed satisfactorily even if the light shield layer 9 and the p-well layer 2 are not given the same potential during manufacture. It is sufficient to design the solid-state imaging device so that the potential difference between the light shield layer 9 and the p-well layer 2 is smaller than or equal to the absolute value of the voltage VL.

When the solid-state imaging device of FIG. 1 is used, the potentials of the light shield layer 9 and the p-well layer 2 can be controlled independently. This makes it possible to use the technique of controlling the potential of the light shield layer 9 variably (as described in JP-A-2003-37262). Even where a parasitic MOS electric field effect is present, it is possible to make use of advantages obtained by utilizing it.

The arrangement of the photoelectric conversion elements is not limited to a square lattice and may be what is called a honeycomb arrangement in which the photoelectric conversion elements on the odd-numbered lines among the lines shown in FIG. 1 are shifted from those on the even-numbered lines in the row direction by ½ of the arrangement pitch of the photoelectric conversion elements. Although the above description is directed to the configuration in which the carriers are electrons, FIGS. 1 to 4A-4C and the related descriptions are also applicable to the case that the carriers are holes if the conductivity types “n” and “p” are interchanged.

It is inferred that a parasitic MOS electric field effect would occur when the thickness of the insulating layer formed between the light shield layer 9 and the n-type silicon substrate 1 is less than or equal to 200 nm in terms of the equivalent oxide thickness. Therefore, the configuration of FIG. 1 is particularly effective in solid-state imaging devices in which the thickness of the insulating layer is less than or equal to 200 nm in terms of the equivalent oxide thickness.

As described above, the following items are disclosed in the specification:

The disclosed solid-state imaging device comprises a first well layer which is formed in a semiconductor substrate, has a conductivity type that is opposite to a conductivity type of the semiconductor substrate, and includes photoelectric conversion elements and a reading unit for reading signals corresponding to charges generated in the respective photoelectric conversion elements; a second well layer formed in the semiconductor substrate and having the conductivity type that is opposite to the conductivity type of the semiconductor substrate; and a light shield layer which is formed over an area where the photoelectric conversion elements are formed, has openings over the respective photoelectric conversion elements, and has contact portions that are in contact with the second well layer.

With this configuration, since the light shield layer and the first well layer can be given the same potential during manufacture, the solid-state imaging device can be prevented from being affected by a plasma surge etc. As a result, a device having a large SN ratio can be provided in which such noise as dark current noise can be reduced. Furthermore, since the potentials of the light shield layer and the first well layer can be controlled independently, smear and the reading voltage can be reduced in the case of a CCD type.

The disclosed solid-state imaging device further comprises an insulating layer which is formed between the semiconductor substrate and the light shield layer and has a thickness that is less than or equal to 200 nm in terms of the equivalent oxide thickness.

The disclosed imaging device comprises either of the above solid-state imaging devices.

The disclosed manufacturing method of a solid-state imaging device comprises a first step of forming, in a semiconductor substrate, a first well layer having conductivity type that is opposite to a conductivity type of the semiconductor substrate and a second well layer having the conductivity type that is opposite to the conductivity type of the semiconductor substrate; a second step of forming, in the first well layer, photoelectric conversion elements and a reading unit for reading signals corresponding to charges generated in the respective photoelectric conversion elements; a third step, executed after the second step, of exposing portions of the second well layer by forming openings in a part, coextending with the second well layer, of a material layer that covers the semiconductor substrate; and a fourth step of forming a light shield layer by depositing a light shield material so that it comes into contact with the portions, exposed through the openings, of the second well layer and forming openings through the light shield material over the respective photoelectric conversion elements.

The disclosed manufacturing method of a solid-state imaging device further comprises a step of forming an insulating layer between the semiconductor substrate and the light shield layer at a thickness that is less than or equal to 200 nm in terms of the equivalent oxide thickness.

What is claimed is:

1. A solid-state imaging device comprising:
a first well layer which is provided in a semiconductor substrate, has a conductivity type that is opposite to a conductivity type of the semiconductor substrate, and comprises photoelectric conversion elements and a reading unit for reading signals corresponding to charges generated in the respective photoelectric conversion elements;
a second well layer provided in the semiconductor substrate and having the conductivity type that is opposite to the conductivity type of the semiconductor substrate; and
a light shield layer which is provided over an area where the photoelectric conversion elements are provided, has openings over the respective photoelectric conversion elements, and has contact portions that are in contact with the second well layer.

2. The solid-state imaging device according to claim 1, further comprising an insulating layer which is provided between the semiconductor substrate and the light shield layer and has a thickness that is less than or equal to 200 nm in terms of an equivalent oxide thickness.

3. An imaging device comprising the solid-state imaging device according to claim 1.

4. A manufacturing method of a solid-state imaging device, comprising:
a first step of forming, in a semiconductor substrate, a first well layer having a conductivity type that is opposite to a conductivity type of the semiconductor substrate and a second well layer having the conductivity type that is opposite to the conductivity type of the semiconductor substrate;
a second step of forming, in the first well layer, photoelectric conversion elements and a reading unit for reading signals corresponding to charges generated in the respective photoelectric conversion elements;
a third step, after the second step, of exposing portions of the second well layer by forming openings in a part, coextending with the second well layer, of a material layer that covers the semiconductor substrate; and
a fourth step of forming a light shield layer by depositing a light shield material so that it comes into contact with the portions, exposed through the openings, of the second well layer and forming openings through the light shield material over the respective photoelectric conversion elements.

5. The manufacturing method of a solid-state imaging device according to claim 4, further comprising a step of forming an insulating layer between the semiconductor substrate and the light shield layer at a thickness that is less than or equal to 200 nm in terms of an equivalent oxide thickness.

6. The manufacturing method of a solid-state imaging device according to claim 4, wherein, in the first step, the first well layer and the second well layer are formed simultaneously.

7. The manufacturing method of a solid-state imaging device according to claim 4, wherein, in the first step, the first well layer and the second well layer are formed separately.
